(19) United States
(12) Patent Application Publication
(10) Pub. No.: US 2023/0364656 A1
(43) Pub. Date: Nov. 16, 2023

(54) METHOD FOR TREATING A SUBSTRATE

(71) Applicant: SEMES CO., LTD., Cheonan-si (KR)

(72) Inventors: Tae-Keun KIM, Suwon-si (KR); Kyeong Min LEE, Hwaseong-si (KR); Min Hee CHO, Suwon-si (KR); Won Young KANG, Gimhae-si (KR)

(73) Assignee: SEMES CO., LTD., Cheonan-si (KR)

(21) Appl. No.: 17/740,772

(22) Filed: May 10, 2022

(51) Int. Cl. B08B 7/00; H01L 21/02

(52) U.S. Cl. CPC B08B 7/0014; H01L 21/02057

(57) ABSTRACT

The inventive concept provides a substrate treating apparatus. The substrate treating apparatus includes discharging a treating liquid including a polymer and a solvent onto a substrate; and solidifying a liquid film of the treating liquid by volatilizing the solvent from the treating liquid on the substrate, and wherein the solidifying a liquid film comprises a first period of stopping the rotation of the substrate or rotating the substrate at a first speed for a first time period.

### TECHNICAL FIELD

Embodiments of the inventive concept described herein relate to a method for treating a substrate, and more specifically to a method for treating a substrate by liquid treating the substrate by supplying a liquid including a polymer to the substrate.

### BACKGROUND

In order to manufacture a semiconductor device, various processes such as a photolithography, a deposition, an ashing, an etching, and an ion implantation are performed. In addition, before and after these processes are performed, a cleaning process is performed to clean particles remaining on the substrate.

One example of cleaning process includes a process of supplying a chemical to a rotating substrate supported by a spin head, a process of supplying a cleaning liquid such as a deionized water (DIW) to the substrate to remove the chemical from the substrate, and then a process of supplying an organic solvent such as an isopropyl alcohol (IPA) liquid with a lower surface tension than the cleaning liquid to the substrate to replace the cleaning liquid on the substrate with the organic solvent, and a process of removing the replaced organic solvent from the substrate.

The cleaning process may include a process of supplying a treating liquid including a polymer and a solvent onto the substrate. Once the solvent containing a volatile component is volatilized, the polymer is solidified due to a change in volume of the treating liquid and adsorb particles. Thereafter, the polymer having adsorbed the particles is peeled off from the substrate by using deionized water, and then the substrate is cleaned again with an organic solvent such as an IPA.

At this time, in order to volatilize the solvent to solidify the polymer, the substrate having a film of the treating liquid is rotated after stopping the supply of treating liquid. However, during the rotating of the substrate having the film of the treating liquid, the treating liquid may be directed to a specific area of the substrate or exit out of an area of patterns on the substrate.

### SUMMARY

Embodiments of the inventive concept provide a substrate treating method that may increase a cleaning efficiency.

Embodiments of the inventive concept provide a substrate treating method that a treating liquid can pass between a pattern formed on a substrate.

The technical objectives of the inventive concept are not limited to the above-mentioned ones, and the other unmentioned technical objects will become apparent to those skilled in the art from the following description.

The inventive concept provides a substrate treating method. The substrate treating method includes discharging a treating liquid including a polymer and a solvent onto a substrate; and solidifying a liquid film of the treating liquid by volatilizing the solvent from the treating liquid on the substrate, and wherein the solidifying a liquid film comprises a first period of stopping the rotation of the substrate or rotating the substrate at a first speed for a first time period.

In an embodiment, during the first period the substrate does not rotate for the first time period.

In an embodiment, the solidifying a solidified thin film further comprises a second period of rotating the substrate at a second speed for a second time period after the first period, the second speed being greater than the first speed.

In an embodiment, the second time period is longer than the first time period.

In an embodiment, the solidifying a thin film comprises stopping a supplying of the treating liquid after the discharging a treating liquid including a polymer and a solvent onto a substrate and rotating the substrate.

In an embodiment, the polymer includes a resin.

The inventive concept provides a substrate treating method. The substrate treating method includes supplying a treating liquid including a polymer and a solvent onto a rotating substrate; and solidifying a thin film of the treating liquid by volatilizing the solvent from the treating liquid, and wherein the solidifying a thin film includes a first period of stopping rotation of the substrate or rotating the substrate at a first speed for a first time period.

In an embodiment, during the first period the substrate does not rotate for the first time period.

In an embodiment, the solidifying a thin film further comprises a second period of rotating the substrate at a second speed for a second time period after the first period, the second speed is greater than the first speed.

In an embodiment, the second time period is longer than the first time period.

In an embodiment, the solidifying a thin film further comprises an initial period of rotating the substrate at a third speed for a third time period before the first period.

In an embodiment, the third time period is a shorter than the first time period.

In an embodiment, the third speed is slower than the second speed.

In an embodiment, the solidifying a film forming includes stopping supplying the treating liquid to the substrate.

In an embodiment, the substrate treating method further comprises after the solidifying a thin film: peeling the solidified thin film of the treating liquid by supplying a peeling liquid to the substrate in a rotating state; cleaning a residue remaining on the substrate by supplying a rinsing liquid to the substrate in a rotating state after peeling the solidified thin film; and drying the substrate in a non-rotating state after the cleaning a residue.

In an embodiment, the polymer includes a resin, the peeling liquid is a deionized water, and the rinsing liquid is an organic solvent.

The inventive concept provides a substrate treating method. The substrate treating method includes supplying a treating liquid including a polymer and a solvent on a substrate in a rotating state; and solidifying a thin film of the treating liquid on the substrate by volatilizing the solvent from the treating liquid while rotating the substrate, and wherein the solidifying a thin film includes a period of stopping the rotating the substrate.

In an embodiment, the solidifying a thin film comprises rotating the substrate for a second time period after a first time period of the stopping the rotation of the substrate, and the second time period is longer than the first time period.

In an embodiment, the solidifying a thin film comprises stopping the supply of the treating liquid to the substrate.

In an embodiment, the polymer includes a resin.

According to an embodiment of the inventive concept, a cleaning efficiency of a substrate may be increased.

According to an embodiment of the inventive concept, an amount of cleaning liquid used by be reduced.

According to an embodiment of the inventive concept, a cleaning liquid may permeate between a pattern formed on a substrate.

The effects of the inventive concept are not limited to the above-mentioned ones, and the other effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view schematically illustrating a substrate treating apparatus according to an embodiment of the inventive concept.

FIG. 2 is a schematically illustrates an embodiment of a liquid treating chamber of FIG. 1.

FIG. 3 is a flowchart of a substrate treating method according to the inventive concept.

FIG. 4 illustrates a state of supplying a treating liquid onto a rotating substrate in the treating liquid supply step.

FIG. 5 illustrates a state in which the treating liquid has been supplied to a substrate.

FIG. 6 illustrates a state in which a substrate rotates in a liquid film forming step.

FIG. 7 is a flowchart of the liquid film forming step according to an embodiment of the inventive concept.

FIG. 8 is a graph illustrating a rotating speed of the substrate in the liquid film forming step.

FIG. 9 to FIG. 13 sequentially illustrate a state of the substrate in the liquid film forming step.

FIG. 14 is a flowchart of the liquid film forming step according to another embodiment of the inventive concept.

FIG. 15 is a illustrates a rotating speed of the substrate in the liquid film forming step according to another embodiment of the inventive concept.

FIG. 16 illustrates a state in which the substrate is rotated in an initial period.

FIG. 17 illustrates a state of supplying a peeling liquid onto the substrate in a liquid film peeling step.

FIG. 18 illustrates a state in which a solidified treating liquid film on the substrate is peeled off in the liquid film peeling step.

FIG. 19 illustrates a state of supplying a rinsing liquid onto a substrate in a rinsing liquid supply step.

FIG. 20 illustrates a state in which the rinsing liquid is supplied onto the substrate.

FIG. 21 illustrates a state of the substrate after the rinsing liquid supply step is completed.

FIG. 22 illustrates a state of rotating the substrate in a drying step.

FIG. 23 illustrates a state of the substrate after the drying step is completed.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms. The embodiment is provided to more fully explain the inventive concept to those with average knowledge in the art. Therefore, a form of the element in the drawing is exaggerated to emphasize a clearer description.

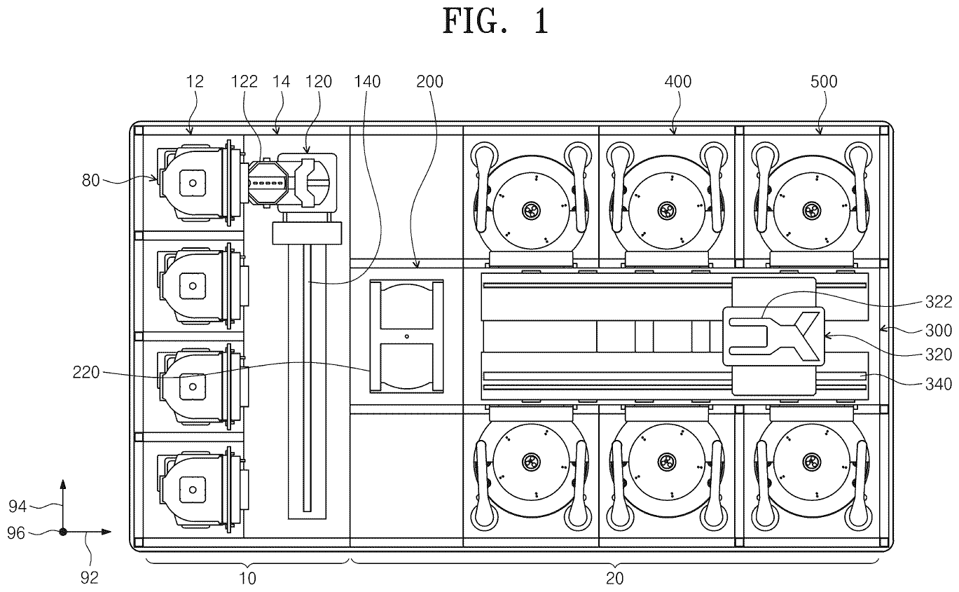

FIG. 1 is a plan view schematically illustrating a substrate treating apparatus according to an embodiment of the inventive concept. Referring to FIG. 1, the substrate treating apparatus includes an index module 10 and a treating module 20. According to an embodiment, the index module 10 and the treating module 20 are disposed in a direction. Hereinafter, the direction in which the index module 10 and the treating module 20 are disposed is referred to as a first direction 92, a direction perpendicular to the first direction 92 is referred to as a second direction 94, and a direction perpendicular to both the first direction 92 and the second direction 94 is referred to as a third direction 96.

The index module 10 transfers the substrate W from a storing container 80 to the treating module 20, and receives and stores a substrate W treated at the treating module 20 to the container 80. A lengthwise direction of the index module 10 is provided in the second direction 94. The index module 10 has a load port 12 and an index frame 14. The load port 12 and the treating module 20 are disposed at two opposite sides of the index module 14, respectively. The container 80 in which substrates W are stored is placed at the load port 12. The load port 12 may be provided in a plurality, and the plurality of load ports 12 may be disposed in the second direction 94.

As the container 80, a sealed container such as a front open unified pod (FOUP) may be used. The container 80 may be placed on the load port 12 by a transfer means (not illustrated) such as an overhead transfer, an overhead conveyor, or an automatic guided vehicle, or by an operator.

The index frame 14 is provided with an index robot 120. A guide rail 140 provided with its lengthwise direction in the second direction 94 may be provided at the index frame 14, and the index robot 120 may be provided to be movable along the guide rail 140. The index robot 120 may include a hand 122 on which the substrate W is placed, and the hand 122 may be provided to be forwardly and backwardly movable, rotatable with the third direction 96 as an axis, and movable along the third direction 96. The hand 122 may be provided in a plurality to be spaced apart in an up/down direction, and the hands 122 may be forwardly and backwardly movable independently of each other.

The treating module 20 includes a buffer unit 200, a transfer chamber 300, and a liquid treating chamber 400. The buffer unit 200 provides a space in which a substrate W carried into the treating module 20 and a substrate W carried out from the treating module 20 temporarily stay. The liquid treating chamber 400 supplies a liquid onto the substrate W to perform a liquid treating process for liquid treating the substrate W. The transfer chamber 300 transfers the substrate W between the buffer unit 200 and the liquid treating chamber 400.

The transfer chamber 300 may be provided with its lengthwise direction in the first direction 92. The buffer unit 200 may be disposed between the index module 10 and the transfer chamber 300. The liquid treating chamber 400 may be disposed on a side of the transfer chamber 300. The liquid treating chamber 400 and the transfer chamber 300 may be disposed in the second direction 94. The buffer unit 200 may be positioned at an end of the transfer chamber 300 adjacent the buffer unit 200.

According to an embodiment, the liquid treating chambers 400 may be disposed on both sides of the transfer chamber 300, and the liquid treating chambers 400 may be provided in an array of A×B (A, B is a natural number greater than 1 or 1), respectively, in the first direction 92 and the third direction 96.

The transfer chamber 300 has a transfer robot 320. A guide rail 340 with its lengthwise direction in the first direction 92 may be provided within the transfer chamber 300, and the transfer robot 320 may be provided to be movable along the guide rail 340. The transfer robot 320 may include a hand 322 on which the substrate W is placed, and the hand 322 may be provided to be forwardly and backwardly movable, rotatable with the third direction 96 as an axis, and movable along the third direction 96. The hand 322 may be provided in a plurality to be spaced apart in the up/down direction, and the hands 322 may be forwardly and backwardly movable independently of each other.

The buffer unit 200 includes a plurality of buffers 220 on which the substrate W is placed. The buffers 220 may be disposed to be spaced apart from each other along the third direction 96. A front face and a rear face of the buffer unit 200 are opened. The front face is a surface facing the index module 10, and the rear face is a surface facing the transfer chamber 300. The index robot 120 may access the buffer unit 200 through the front face, and the transfer robot 320 may access the buffer unit 200 through the rear face.

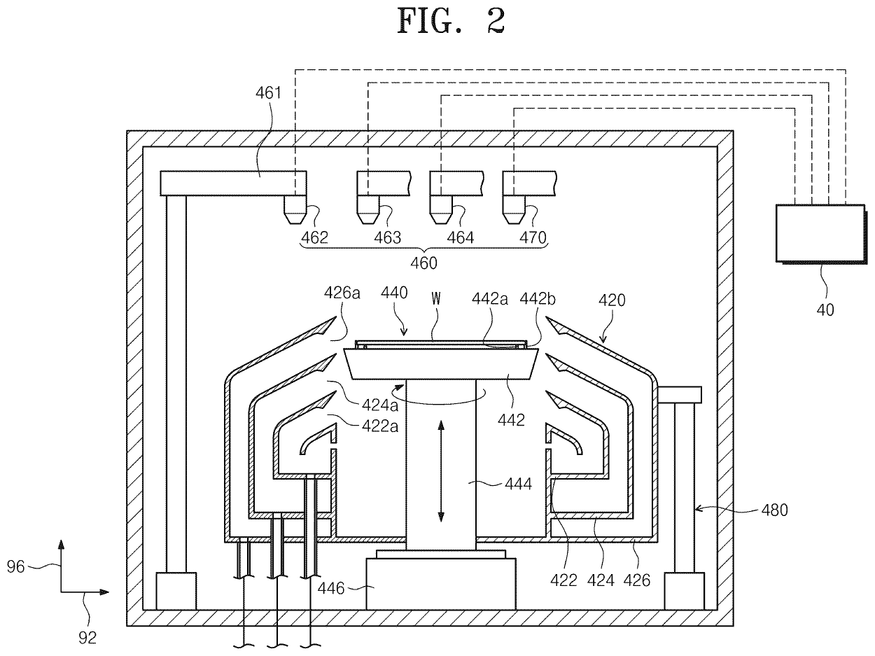

FIG. 2 is a view schematically illustrating an embodiment of the liquid treating chamber 400 of FIG. 1. Referring to FIG. 2, the liquid treating chamber 400 includes a housing 410, a cup 420, a support unit 440, a liquid supply unit 460 and a lifting/lowering unit 480.

The housing 410 is provided in a substantially rectangular parallelepiped shape. The cup 420, the support unit 440, and the liquid supply unit 460 are disposed within the housing 410.

The cup 420 has a treating space with an open top, and the substrate W is liquid-treated in the treating space. The support unit 440 supports the substrate W within the treating space. The liquid supply unit 460 supplies a liquid onto the substrate W supported by the support unit 440. The liquid is provided in a plurality of types and sequentially supplied onto the substrate W. The lifting/lowering unit 480 adjusts a relative height between the cup 420 and the support unit 440.

According to an embodiment, the cup 420 has a plurality of recollecting containers 422, 424, and 426. Each of the recollecting containers 422, 424, and 426 has a recollecting space for recollecting the liquid used for a substrate treatment. Each of the recollecting containers 422, 424, and 426 is provided in a ring shape surrounding the support unit 440. When the liquid treating process proceeds, the treating liquid scattered by a rotation of the substrate W flows into the recollecting space through inlets 422a, 424a, and 426a of each of the respective recollecting containers 422, 424, and 426.

According to an embodiment, the cup 420 has a first collecting container 422, a second collecting container 424, and a third collecting container 426. The first collecting container 422 is disposed to surround the support unit 440, the second collecting container 424 is disposed to surround the first collecting container 422, and the third collecting container 426 is disposed to surround the second collecting container 424. The second inlet 424a through which a liquid flows into the second recollecting container 424 may be located above the first inlet 422a through which a liquid flows into the first recollecting container 422, and the third inlet 426a through which a liquid flows into the third recollecting container 426 may be located above the second inlet 424a.

The support unit 440 has a support plate 442 and a drive shaft 444. A top surface of the support plate 442 is generally provided in a circular shape and may have a diameter larger than that of the substrate W. A support pin 442a for supporting a bottom surface of the substrate W is provided at a center of the support plate 442, and the support pin 442a is provided such that a top end thereof protrudes from the support plate 442 so that the substrate W is spaced apart from the support plate 442 by a predetermined distance.

A chuck pin 442b is provided at an edge of the support plate 442. The chuck pin 442b is provided to upwardly protrude from the support plate 442, and supports a side of the substrate W so that the substrate W is not laterally out of the support unit 440 when the substrate W is rotated. The drive shaft 444 is driven by a driver 446, is connected to a center of the bottom surface of the substrate W, and rotates the support plate 442 on its central axis.

The lifting/lowering unit 480 moves the cup 420 in the up/down direction. A relative height between the cup 420 and the substrate W is changed by an up/down movement of the cup 420. Accordingly, since the recollecting containers 422, 424, and 426 for recollecting the treating liquid are changed according to a type of liquid supplied to the substrate W, the liquid may be separately recollected. Unlike described above, the cup 420 is fixedly installed, and the lifting/lowering unit 480 may move the support unit 440 in the up/down direction.

Referring to FIG. 2, the inventive concept may include a liquid supply unit 460 and a controller 40 controlling the liquid supply unit 460. The liquid supply unit 460 includes a solution supply nozzle 463, a peeling liquid supply nozzle 462, a rinsing liquid supply nozzle 464, and a treating liquid supply nozzle 470. In an embodiment, the solution supply nozzle 463, the peeling liquid supply nozzle 462, the rinsing liquid supply nozzle 464, and the treating liquid supply nozzle 470 may be supported by a different arm 461. Selectively, the solution supply nozzle 463, the peeling liquid supply nozzle 462, the rinsing liquid supply nozzle 464, and the treating liquid supply nozzle 470 may be supported by a same arm 461.

The solution supply nozzle 463 supplies a solution onto the substrate W supported by the support unit 440. According to an embodiment, the solution is a liquid that dissolves a polymer to be described later. According to one embodiment, the solution is an organic solvent. According to an embodiment, the solution may be provided with any one of an isopropyl alcohol (IPA), a thinner, a butanol, a propylene glycol methyl ether (PGME), and a methyl isobutyl carbinol (MIBC), or combinations thereof.

The peeling liquid supply nozzle 462 discharges a peeling liquid onto the substrate W. According to an embodiment, the peeling liquid contains a deionized water. The peeling liquid applies a physical impact to the treating liquid film formed on the substrate W to peel the liquid film from the substrate W.

The rinsing liquid supply nozzle 464 discharges a rinsing liquid onto the substrate W. In an embodiment, the rinsing liquid includes a liquid dissolving the polymer. According to an embodiment, the rinsing liquid contains an organic solvent. According to an embodiment, the rinsing liquid may be provided with any one of an isopropyl alcohol (IPA), a thinner, a butanol, a propylene glycol methyl ether (PGME), and a methyl isobutyl carbinol (MIBC), or combinations thereof.

In the above-described example, it has been described that the solution supply nozzle 463 and the rinsing liquid supply nozzle 464 are separately provided. However, unlike this, the solution supply nozzle 463 and the rinsing liquid supply nozzle 464 d may be provided as a single nozzle which supplies both the solution and the rinsing liquid.

The treating liquid supply nozzle 470 supplies the treating liquid including a polymer onto the substrate W, thereby forming a liquid film on the substrate W. The treating liquid includes a polymer and a solvent. The polymer includes a resin. The resin may be an acrylic resin, a phenol resin, etc. The treating liquid is a liquid in which the polymer is dissolved in a solvent. When the treating liquid on the substrate W (the liquid film) is dried, the solvent evaporates and the remaining polymer on the substrate W is solidified to form a solidified polymer film (solidified liquid film).

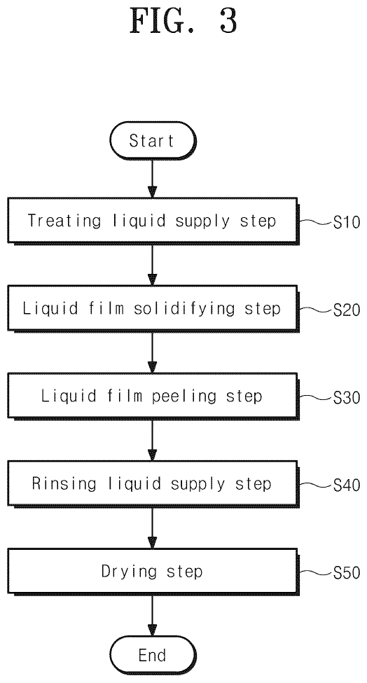

Hereinafter, a substrate treating method according to the inventive concept will be described with reference to FIG. 3 to FIG. 23.

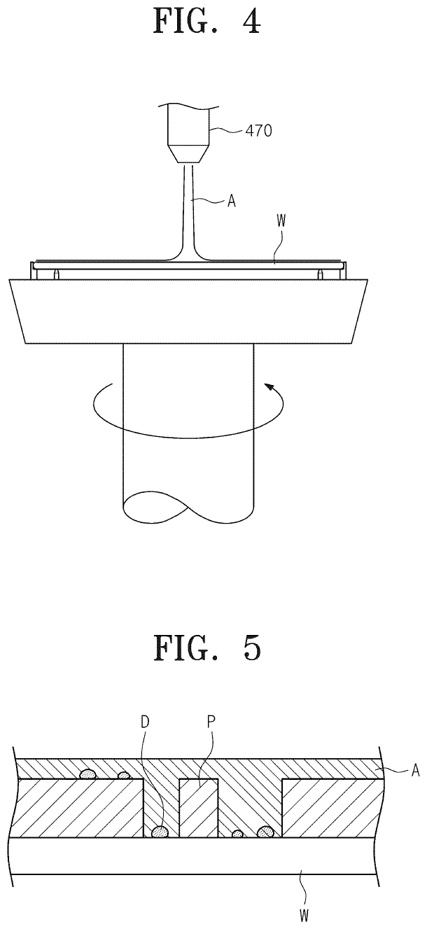

FIG. 3 is a flowchart of a substrate treating method of the inventive concept, FIG. 4 illustrates a state of supplying the treating liquid A onto a rotating substrate W in the treating liquid supply step S10, and FIG. 5 illustrates a state in which the treating liquid A is supplied to the substrate W. Referring to FIG. 3, the substrate treating method of the inventive concept includes a treating liquid supply step S10, a liquid film solidifying step S20, a liquid film peeling step S30, a rinsing liquid supply step S40, and a drying step S50.

In the treating liquid supply step S10, as shown in FIG. 4, the treating liquid A is supplied onto the rotating substrate W. In an embodiment, the treating liquid supply nozzle 470 supplies the treating liquid A above a central region of the substrate W. By the rotation of the substrate W, the treating liquid A spreads from the center of the substrate W to the edge region. When the treating liquid A is supplied onto the substrate W, as shown in FIG. 5, a liquid film of the treating liquid A is formed on the substrate W. Once the treating liquid A is supplied to the substrate W having pattern P, the resulting liquid film of the treating liquid A may capture the particles D positioned between the pattern P.

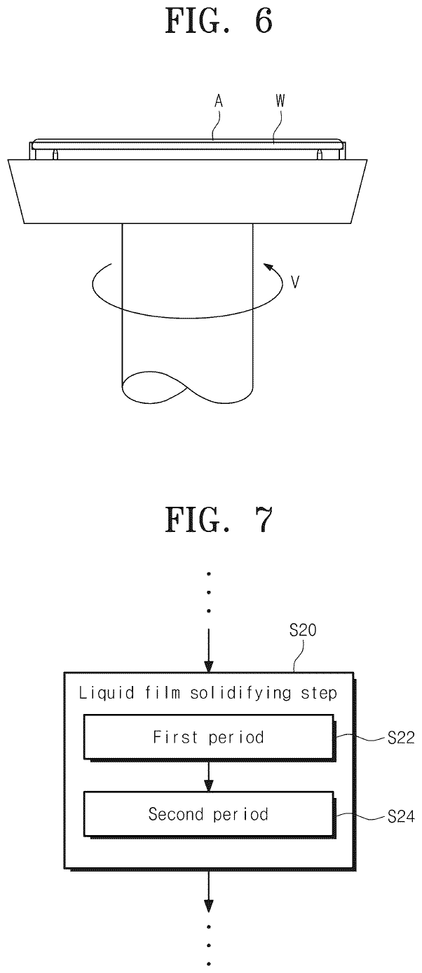

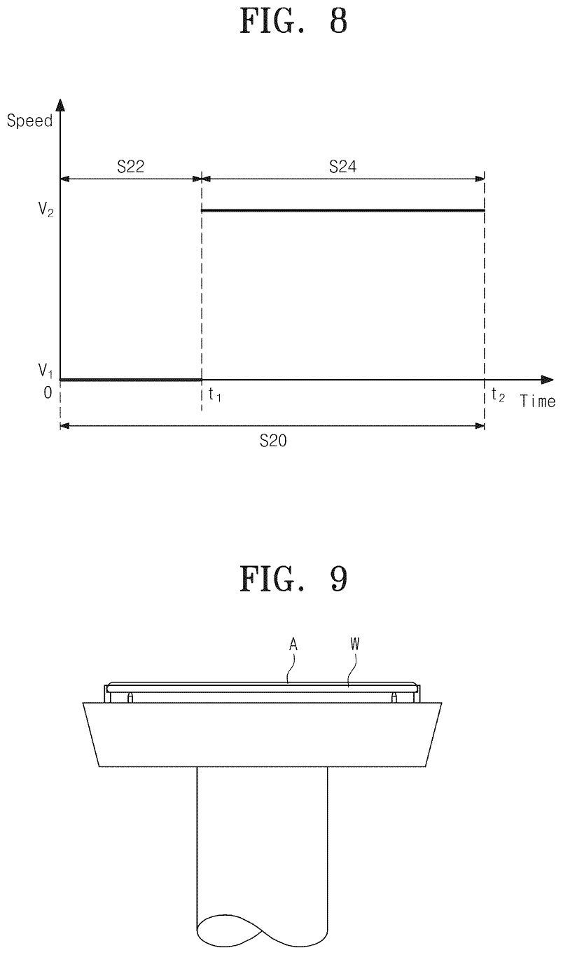

After the treating liquid supply step S10, a liquid film solidifying step S20 begins. FIG. 6 illustrates a state in which the substrate W rotates in the liquid film solidifying step S20, FIG. 7 illustrates a flowchart of the liquid film solidifying step S20, FIG. 8 illustrates a rotation speed of the substrate W in the liquid film solidifying step S20, and FIG. 9 to FIG. 13 sequentially illustrate a state of the substrate at the liquid film solidifying step S20.

Referring to FIG. 6, the liquid film solidifying step S20 may include rotate in multi-period the substrate W without supplying a liquid on the substrate W. However, in an embodiment, the liquid film solidifying step S20 of the inventive concept may include a period in which the rotation of the substrate W is stopped. Referring to FIG. 7, the liquid film solidifying step S20 of the inventive concept includes a first period S22 and a second period S24. In an embodiment, as illustrated in FIG. 8, the first period S22 include stopping rotation of the substrate or rotating the substrate at a first speed V1 for a first time period t1, and the second period S24 include rotating the substrate at a second speed V2 for a second time period t2−t1.

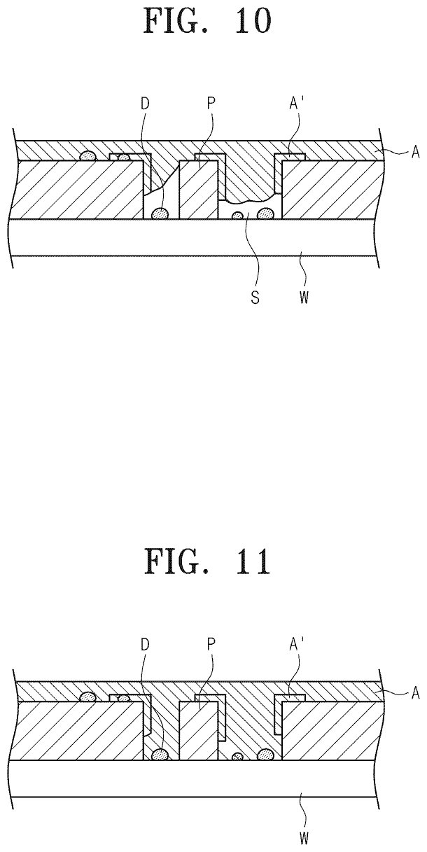

In an embodiment, the first speed V1 may include 0. For example, as shown in FIG. 9, the substrate may not rotate for the first time period t1. The treating liquid A supplied onto the substrate may be solidified near a pattern P. Thus, the solidified treating liquid A′ may prevent the treating liquid A from reaching and filling spaces between the patterns P. Thus, if the substrate rotates at high speed as illustrated in FIG. 10, in a vicinity of the solidified treating liquid A′, the treating liquid A cannot pass between the patterns P, resulting in an empty space S. Since the particles D present in the empty space S may not be captured by the treating liquid A, the particles D may not be removed from the substrate W afterwards. Accordingly, embodiments of the inventive concept may include a process of a stopping of the rotation of the substrate W in the liquid film solidifying step S20, so that a generation of the empty space does not occur near the solidified treating liquid A′. If the substrate W continuously rotates, an unsolidified treating liquid exits from between patterns P near the solidified treating liquid A′, or the unsolidified treating liquid is scattered from a center region toward an edge region of the substrate W due to a rotational speed of the substrate W. Accordingly, in the embodiments of the inventive concept, when the rotation of the substrate W is stopped, as illustrated in FIG. 11, the treating liquid A passes between the solidified treating liquid A′ and reaches down to a bottom surface between the patterns P.

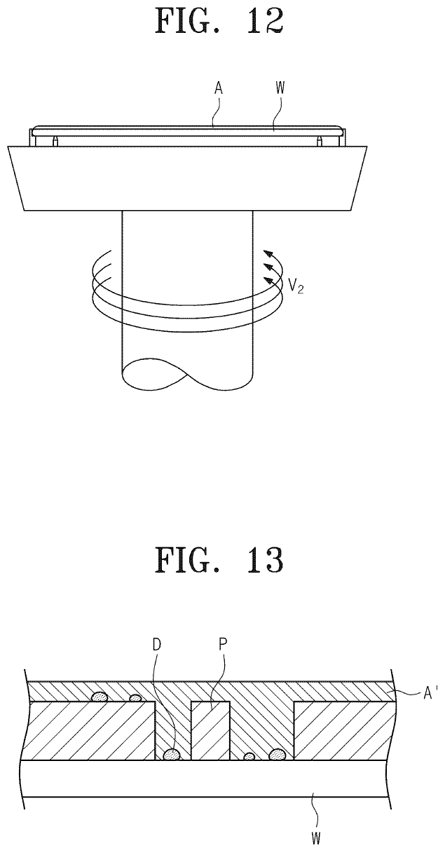

When the treating liquid A pass between the solidified treating liquid A′ and reaches down to a bottom surface between the patterns P, as illustrated in FIG. 12, the substrate W is rotated at the second speed V2 for a second time period t241 at the second period S24. In an embodiment, the second time period t241 is provided as a time longer than the first time period t1. In an embodiment, the second time period t241 may be provided as 50% to 150% long as those of the first time t1. For example, the second time period t241 may be provided twice as long as the first time period t1. Accordingly, the treating liquid A is sufficiently solidified on the substrate W.

In an embodiment, in the second period S24, a rotation speed V2 of the substrate W is provided equal to a rotation speed of the substrate W at the treating liquid supply step S10. Selectively, in the liquid film solidifying step S20, the rotation speed of the substrate W is provided slower or faster than the rotation speed of the substrate W in the treating liquid supply step S10. In the second period S24, the solvent within the treating liquid A is evaporated and the treating liquid A is solidified on the substrate W. Accordingly, as shown in FIG. 13, a film of the solidified treating liquid A′ is formed on the substrate W. As shown in FIG. 13, particles D are captured within a solidified treating liquid A′.

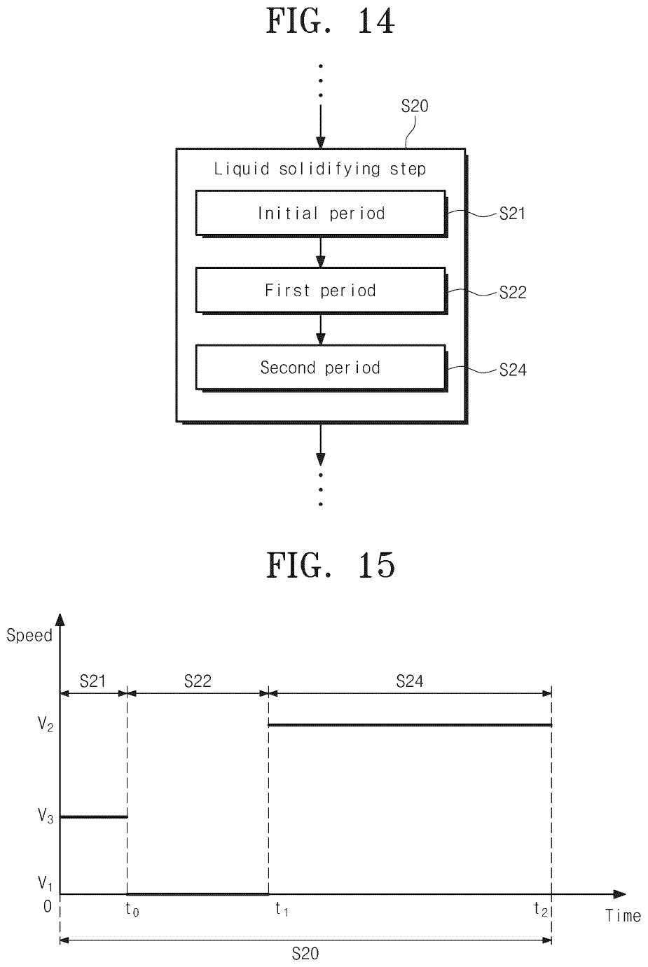

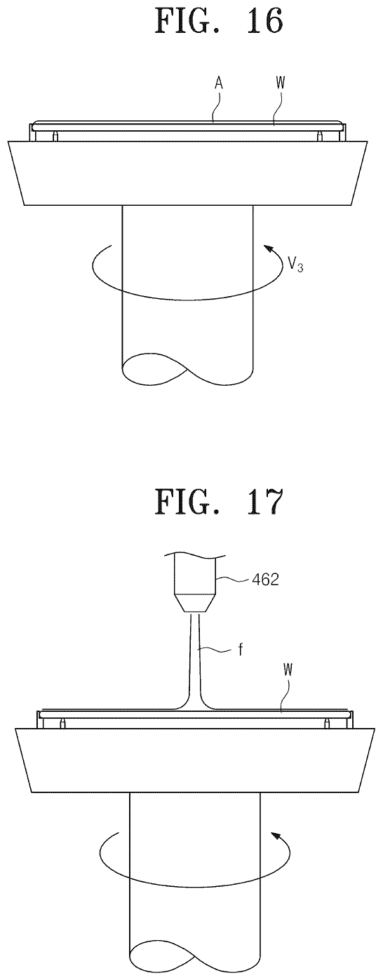

FIG. 14 is a flowchart of the liquid film forming step according to another embodiment of the inventive concept, FIG. 15 illustrates a rotation speed of the substrate W in the liquid film solidifying step according to another embodiment of the inventive concept, and FIG. 16 illustrates a rotation of the substrate W at an initial period S21.

Referring to FIG. 14, in an embodiment, the liquid film solidifying step S20 includes an initial period S21, a first period S22, and a second period S24. In an embodiment, the first period S22 and the second r period S24 may proceed in the same manner as described above. In the initial period S21, the substrate W is rotated at a third speed V3 for a third time period t0 as shown in FIG. 16. In an embodiment, the third speed V3 is a speed that is not zero. In an embodiment, the third speed V3 is provided at a speed slower than the second speed V2.

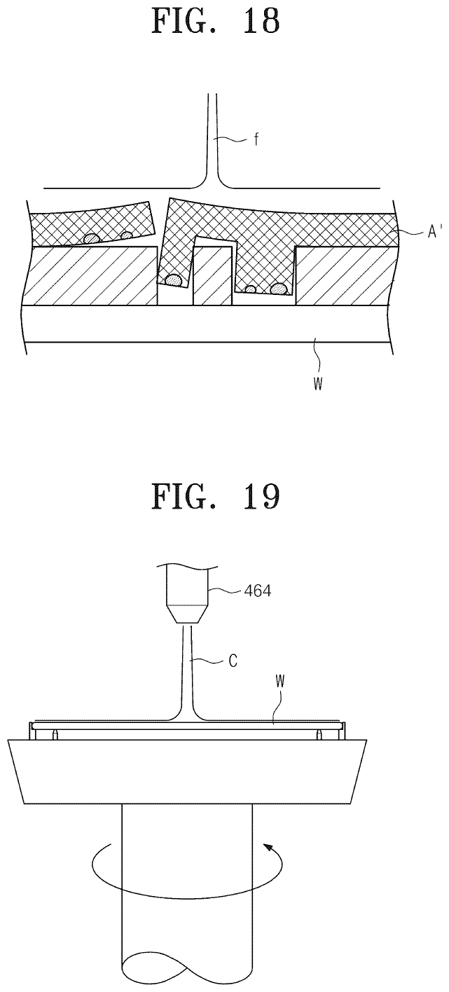

After the liquid film solidifying step S20, the liquid film peeling step S30 is performed. FIG. 17 shows a state of supplying the peeling liquid F onto the substrate W in the liquid film peeling step S30, and FIG. 18 shows a state in which the solidified treating liquid A′ on the substrate W is peeled off in the liquid film peeling step S30. As shown in FIG. 17, in the liquid film peeling step S30, the peeling liquid F is supplied onto the rotating substrate W to peel off the solidified treating liquid A′ on the substrate W together with the particles D on the substrate W. In an embodiment, the peeling liquid F supply nozzle 462 supplies the peeling liquid F to the central region of the substrate W. By the rotation of the substrate W, the peeling liquid F spreads from the center to the edge region of the substrate W. The particles D captured by (immobilized in) the solidified treating liquid A′ are peeled off from the substrate W together with the solidified treating liquid A′. The peeling liquid F applies a physical force to the solidified treating liquid A′ so that the solidified treating liquid A′ is separated from the substrate W as illustrated in FIG. 18.

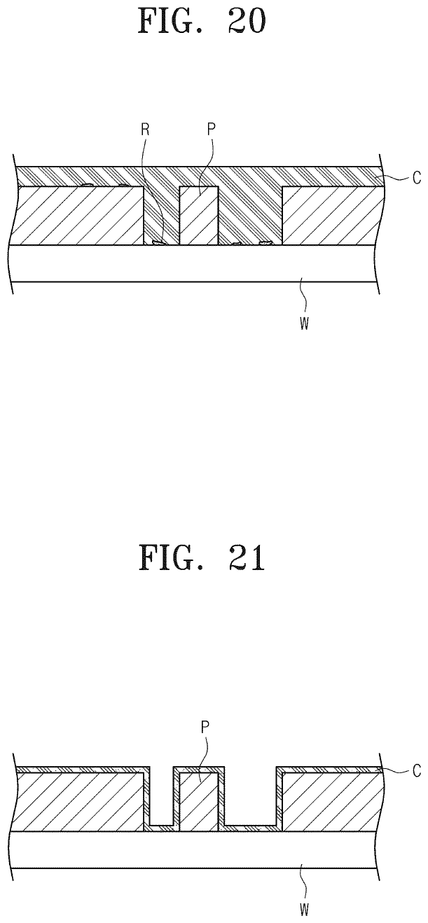

After the liquid film peeling step S30, the rinsing liquid supplying step S40 is performed. FIG. 19 shows a state of supplying a rinsing liquid C onto the substrate W in the rinsing liquid supply step S40, and FIG. 20 shows a state in which the rinsing liquid C is supplied onto the substrate W.

As shown in FIG. 19, in the rinsing liquid supply step S40, the rinsing liquid C supply nozzle 464 supplies the rinsing liquid C onto the rotating substrate W to remove a remaining residue on the substrate W. Even if the substrate W is cleaned by supplying the peeling liquid F in the liquid film peeling step S30, foreign substances may remain on the substrate W as shown in FIG. 20. Accordingly, the rinsing liquid C is supplied onto the substrate W to remove the residue. In an embodiment, the rinsing liquid C supply nozzle 464 supplies the rinsing liquid C onto the central region of the substrate W. By the rotation of the substrate W, the rinsing liquid C spreads from the center to the edge region of the substrate W, thereby removing the residue.

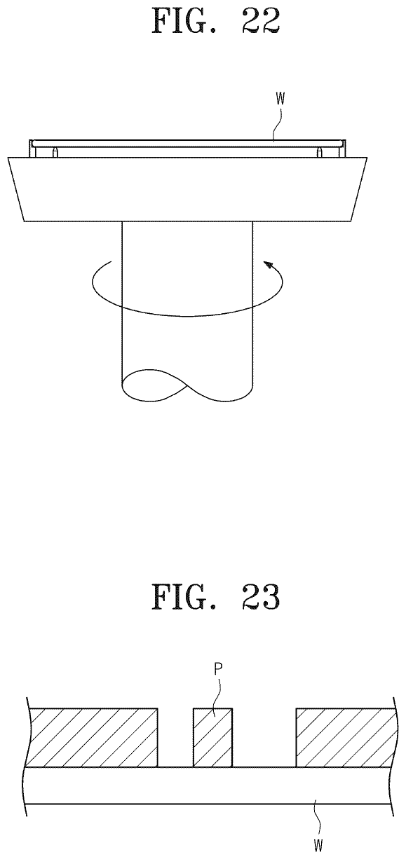

After the rinsing liquid supply step S40, the drying step S50 is performed. FIG. 21 illustrates a state of the substrate W after the rinsing liquid supply step S40, FIG. 22 illustrates a state of rotating the substrate W in the drying step S50, and FIG. 23 illustrates a state of the substrate W after the drying step S50. As shown in FIG. 21, the rinsing liquid C supplied onto the substrate W in the rinsing liquid supply step S40 removes the residue, but the rinsing liquid C itself may remain on the substrate W. Accordingly, in the drying step S50, the rinsing liquid C remaining on the substrate W is dried. In an embodiment, in the drying step S50, as shown in FIG. 22, the substrate W is rotated in a state in which a supplying of a liquid is stopped on the substrate W. When the drying step S50 is completed, as shown in FIG. 23, the substrate W is cleaned without any material remaining between the pattern P.

As described above, in each step, the substrate W is provided in a rotated state while a liquid is discharged. However, the substrate W may not rotate in each step.

As described above, it has been described that each nozzle supplies a liquid onto the central region of the substrate W. However, selectively, an impact point of each nozzle may be changed between the central region and the edge region of the substrate W.

According to an embodiment of the inventive concept, after a step of supplying the treating liquid containing a polymer onto the substrate, a step of solidifying a liquid film may be performed by a stopping of a supplying of a liquid onto the substrate the step of solidifying a liquid film may include a period of stopping a rotation of the substrate for a certain time period. Accordingly, the treating liquid pass and reach between the pattern of the substrate, thereby increasing a cleaning efficiency of the substrate.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating method comprising:
discharging a treating liquid including a polymer and a solvent onto a substrate; and
solidifying a liquid film of the treating liquid by volatilizing the solvent from the treating liquid on the substrate, and
wherein the solidifying a liquid film comprises a first period of stopping the rotation of the substrate or rotating the substrate at a first speed for a first time period.

2. The substrate treating method of claim 1, wherein during the first period the substrate does not rotate for the first time period.

3. The substrate treating method of claim 1, wherein the solidifying a solidified thin film further comprises a second period of rotating the substrate at a second speed for a second time period after the first period, the second speed being greater than the first speed.

4. The substrate treating method of claim 3, wherein the second time period is longer than the first time period.

5. The substrate treating method of claim 1, wherein the solidifying a thin film comprises stopping a supplying of the treating liquid.

6. The substrate treating method of claim 5, wherein the polymer includes a resin.

7. A substrate treating method comprising:
supplying a treating liquid including a polymer and a solvent onto a rotating substrate; and
solidifying a thin film of the treating liquid by volatilizing the solvent from the treating liquid, and
wherein the solidifying a thin film includes a first period of stopping rotation of the substrate or rotating the substrate at a first speed for a first time period.

8. The substrate treating method of claim 7, wherein during the first period the substrate does not rotate for the first time period.

9. The substrate treating method of claim 7, wherein the solidifying a thin film further comprises a second period of rotating the substrate at a second speed for a second time period after the first period, the second speed is greater than the first speed.

10. The substrate treating method of claim 9, wherein the second time period is longer than the first time period.

11. The substrate treating method of claim 9, wherein the solidifying a thin film further comprises an initial period of rotating the substrate at a third speed for a third time period before the first period.

12. The substrate treating method of claim 11, wherein the third time period is a shorter than the first time period.

13. The substrate treating method of claim 11, wherein the third speed is slower than the second speed.

14. The substrate treating method of claim 7, wherein the solidifying a film forming includes stopping supplying the treating liquid to the substrate.

15. The substrate treating method of claim 7, further comprising, after the solidifying a thin film:
peeling the solidified thin film of the treating liquid by supplying a peeling liquid to the substrate in a rotating state;
cleaning a residue remaining on the substrate by supplying a rinsing liquid to the substrate in a rotating state after peeling the solidified thin film; and
drying the substrate in a non-rotating state after the cleaning a residue.

16. The substrate treating method of claim 15, wherein the polymer includes a resin, the peeling liquid is a deionized water, and the rinsing liquid is an organic solvent.

17. A substrate treating method comprising:
supplying a treating liquid including a polymer and a solvent on a substrate in a rotating state; and
solidifying a thin film of the treating liquid on the substrate by volatilizing the solvent from the treating liquid while rotating the substrate, and
wherein the solidifying a thin film includes a period of stopping the rotating the substrate.

18. The substrate treating method of claim 17, wherein the solidifying a thin film comprises rotating the substrate for a second time period after a first time period of the stopping the rotation of the substrate, and the second time period is longer than the first time period.

19. The substrate treating method of claim 17, wherein the solidifying a thin film comprises stopping the supply of the treating liquid to the substrate.

20. The substrate treating method of claim 19, wherein the polymer includes a resin.
